(19) United States
(12) Patent Application Publication
(10) Pub. No.: US 2014/0118905 A1
(43) Pub. Date: May 1, 2014

(54) PROTECTIVE CASE FOR PORTABLE ELECTRONIC DEVICE

(71) Applicants: FIH (Hong Kong) Limited, Kowloon (HK); SHENZHEN FUTAIHONG PRECISION INDUSTRY CO., LTD., Shenzhen (CN)

(72) Inventors: HUAN-CHANG CHUNG, Shindian (TW); ZHONG-SHU QIN, Shenzhen (CN); GANG YANG, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/973,080

(22) Filed: Aug. 22, 2013

(30) Foreign Application Priority Data
Oct. 26, 2012 (CN) 2012104160335

(51) Int. Cl. A45C 11/22; H05K 5/06; H05K 5/00

(52) U.S. Cl. CPC A45C 11/22; H05K 5/0086; H05K 5/061
USPC 361/679.01; 206/37

(57) ABSTRACT

A protective case is used for protecting an electronic device. The protective case includes a housing, a first sealing member, a second sealing member and two slidable covers. The housing includes a main plate and a peripheral wall, the main plate and the peripheral cooperatively define a receptacle. The first sealing member is received in the receptacle and is secured on the main plate. The second sealing member includes a sealing ring for abutting against the peripheral wall. The two slidable covers slidably engage with the peripheral wall of the housing and latched to the housing.

### BACKGROUND

1. Technical Field

The exemplary disclosure relates to cases for portable electronic devices, particularly, to a protective case for protecting portable electronic devices.

2. Description of Related Art

Protective cases are used to protect portable electronic devices of many different types and configurations, including but not limited to PDAs, tablet style personal computer (tablet PC), laptop computer, notebook, and personal stereos, thereby the display of the portable electronic device can be protected when not in use. However, typical protective cases cannot efficiently prevent the electronic device from dust or water.

Therefore, there is room for improvement within the art.

### BRIEF DESCRIPTION OF THE DRAWINGS

Many aspects of the protective case can be better understood with reference to the following drawings. The components in the drawings are not necessarily drawn to scale, the emphasis instead being placed upon clearly illustrating the principles of the protective case.

FIG. 1 is an exploded view of a protective case and an electronic device protected by the protective case according to an exemplary embodiment.

FIG. 2 is similar to FIG. 1, but shown from another aspect.

FIG. 3 is an enlarged view of a circular portion III shown in FIG. 2.

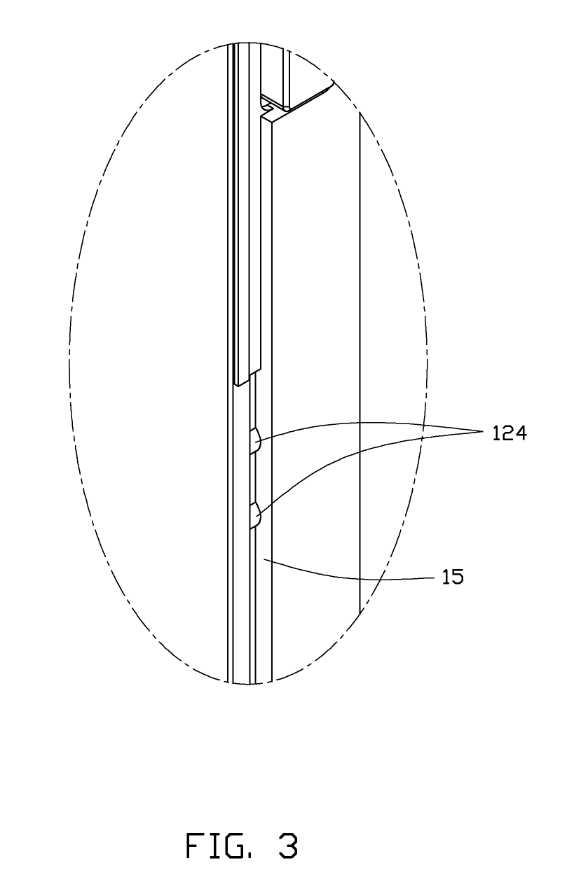

FIG. 4 is an assembled view of the protective case of FIG. 1.

FIG. 5 is similar to FIG. 4, but shown from another aspect.

FIG. 6 is a cross sectional view of the protective case of FIG. 4 along the line of VI-VI.

### DETAILED DESCRIPTION

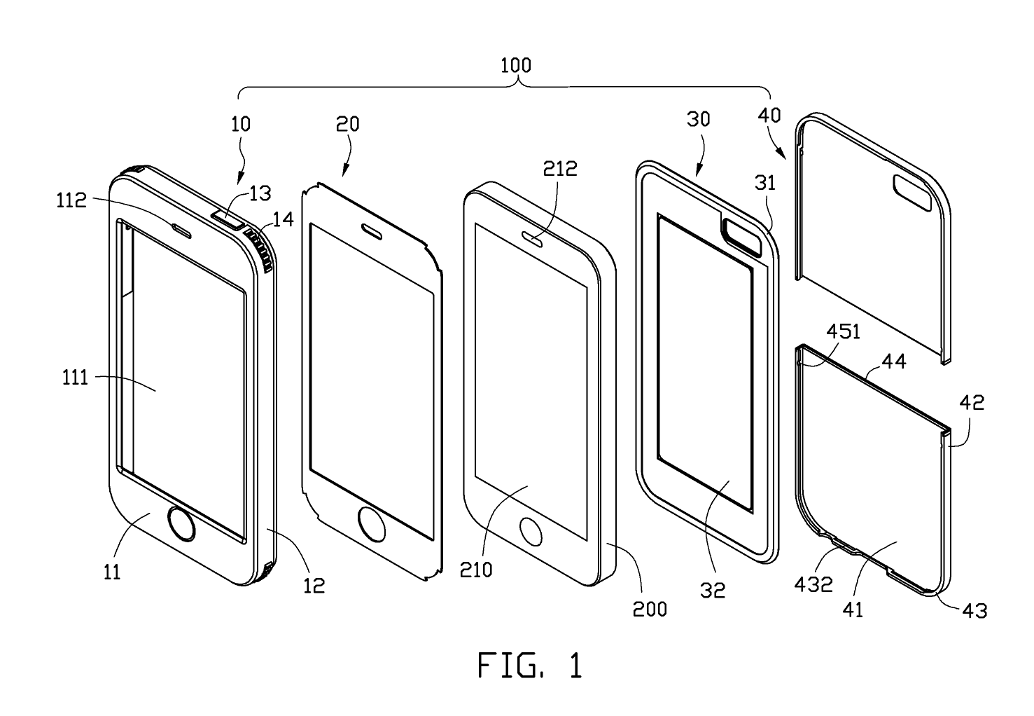

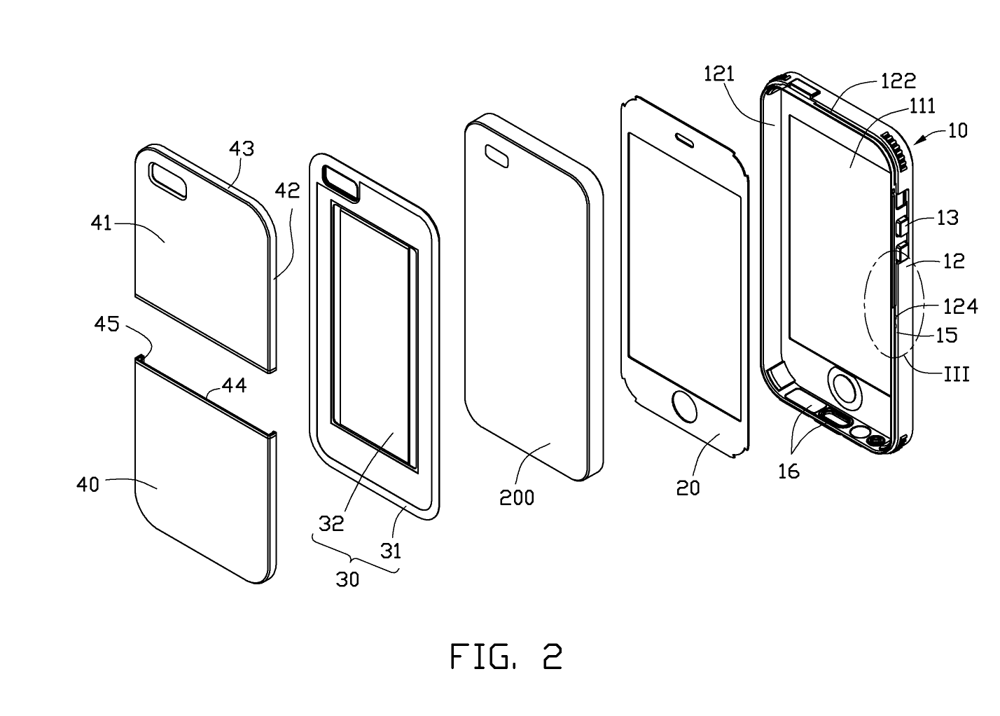

FIGS. 1 to 2 show an exemplary embodiment of a protective case 100. The case 100 is used to receive and protect an electronic device 200 like shown in FIGS. 1 and 2. The case 100 includes a housing 10, a first sealing member 20 fixed to the housing 10, a second sealing member 30, and two slidable covers 40. The two slidable covers 40 are slidably attached to the housing 10. The electronic device 200 is received in the protective case 100. The electronic device 200 has a display area 210 and a microphone area 212 at one surface. A plurality of side buttons (not shown) and a plurality of ports (now shown) are positioned at a peripheral surface of the electronic device 200.

The housing 10 includes a main plate 11, a peripheral wall 12 protruding from an peripheral edge of the main plate 11 and surrounding the main plate 11. The main plate 11 and the peripheral wall 12 cooperatively define a receptacle 121 for accommodating the electronic device 200. The main plate 11 defines an opening 111 for exposing the display 210 and a shielding microphone portion 112. The shielding microphone portion 112 corresponds to the microphone area 212, and is for fixing inside of the main plate 11. In this exemplary embodiment, the shielding microphone portion 112 is made of very fine mesh, and is adhered in the inside of the main plate 11 for preventing water/dust from entering the microphone area 212. The mesh needs to allow the sound of the microphone to transmit from the shielding microphone portion 112.

The peripheral wall 12 has a plurality of shielding button portions 13 and four bumpers 14. The position and the shape of the shielding button portions 13 correspond to the side buttons on the electronic device 200 for protecting the side buttons. The four bumpers 14 are respectively positioned at four corners of the peripheral wall 12 for buffering the housing 10 when the housing 10 is dropped. Each bumper 14 is made of a plurality of equidistantly spaced ribs protruding from the housing 10. In this exemplary embodiment, the shielding button portions 13 and the four bumpers 14 are made of thermoplastic material, such as thermoplastic polyurethane, and are integrally formed with the housing 10 by dual-injection molding. The peripheral wall 12 has a plurality of shielding port portions 16 corresponding to the ports on the electronic device 200. The shielding port portions 16 are made of elastic material, and are detachably latched to the housing 10 for covering the ports on the electronic device 200.

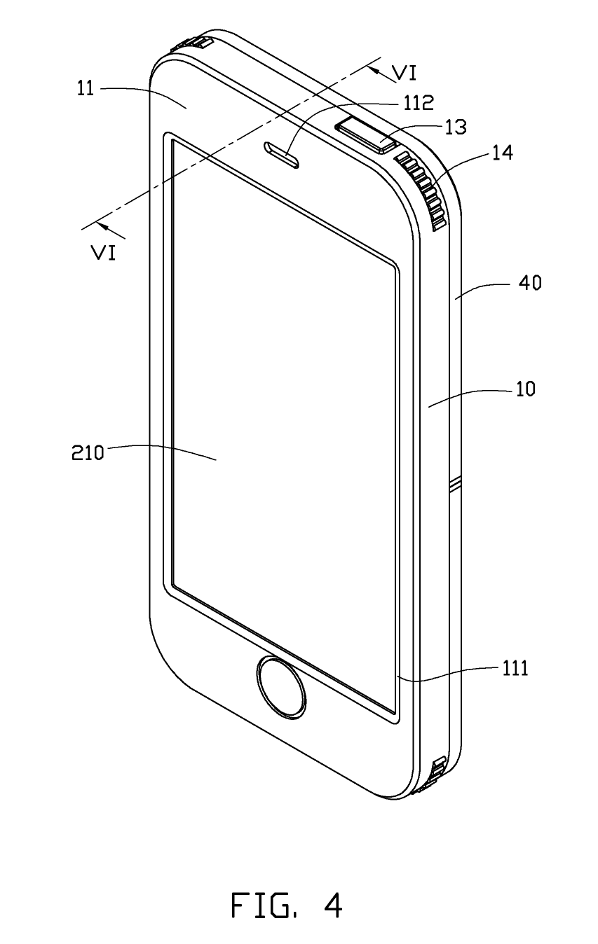

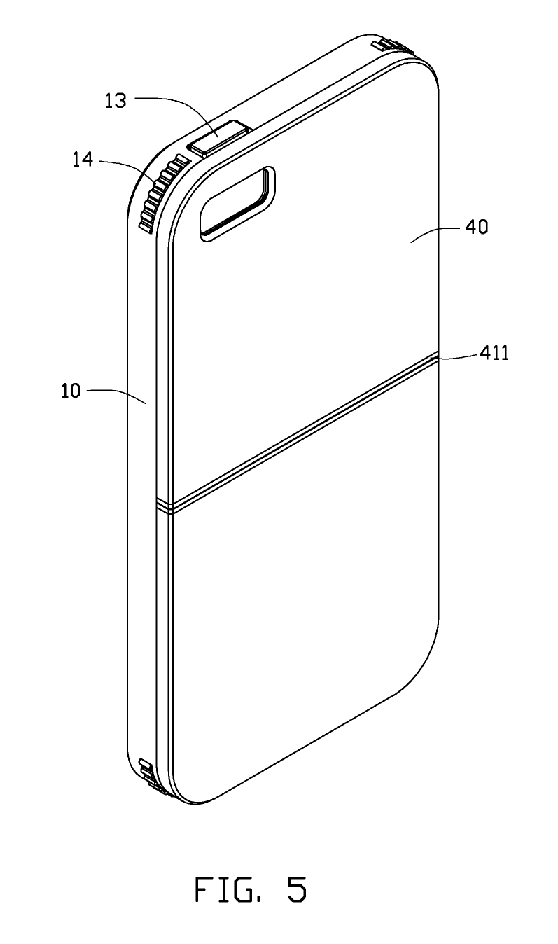

The peripheral wall 12 has a guide groove 15, which extends continuously around all sides of the peripheral wall 12. Opposite ends of the peripheral wall 12 have at least one protrusion 122 configured for positioning a corresponding slidable cover 40. Referring to FIG. 4, opposite sides of the peripheral wall 12 have two projections 124 configured for latching the two slidable covers 40. Referring to FIG. 5, the peripheral wall 12 has a first sloping surface 120 for engaging with the second sealing member 20.

The first sealing member 20 is secured on an inside surface of the main plate 11 of the housing 10, and surrounds the opening 111 of the housing 10. The first sealing member 20 has a shape similar to the main plate 11, and is used for sealing the display 210 of the electronic device 200 for preventing dust/water from entering the display 210. In this exemplary embodiment, the first sealing member 20 is made of waterproof material, such as waterproof sponge, and is adhered on the inside surface of the main plate 11 by adhesive.

The second sealing member 30 includes a rectangular sealing ring 31 and a reinforcing plate 32. The sealing ring 31 surrounds a peripheral edge of the reinforcing plate 32. The reinforcing plate 32 is made of plastics and the sealing ring 31 is made of thermoplastic polyurethane. The reinforcing plate 32 and the sealing ring 31 are integrally formed with each other by dual-injection molding. The sealing ring 31 has a second sloping surface 310 for abutting against the first sloping surface 120.

FIG. 4 shows that the two slidable covers 40 are slidably attached to opposite ends of the housing 10. Each slidable cover 40 includes a cover body 41, two opposite sidewalls 42 and an end wall 43 connected to each other. The end wall 43 is connected between the two opposite sidewalls 42. The end wall 43 defines at least one positioning groove 432 for engaging with the protrusions 122. One end of the cover body 41 opposite to the end wall 43 has a sealing beam 44 for sealing a gap between the two slidable covers 40. An extending edge 45 extends substantially perpendicularly from the opposite sidewalls 42 and the end wall 43 for being slidable received in the guide groove 15. Opposite sides of the extending edge 45 defines a latching groove 451 for engaging with the projections 124.

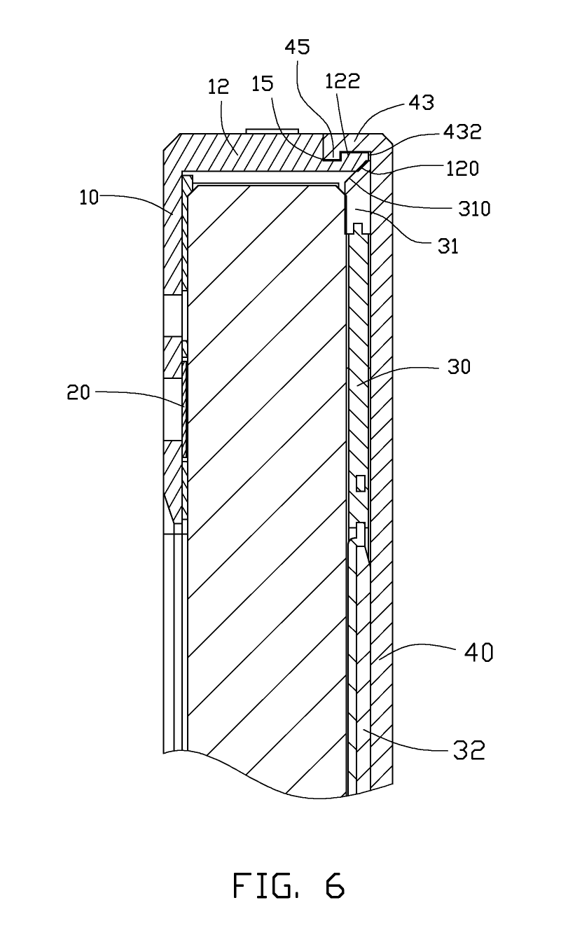

FIGS. 5 to 6 show that in use, the electronic device 200 is received in the receptacle 121. At this time, the first sealing member 20 contacts with and encloses the display 210. The shielding microphone portion 112 corresponds to the microphone area 212. The peripheral wall 12 surrounds a peripheral edge of the electronic device 200. The shielding button portions 13 cover the button, and the shielding port portions 16 covers the ports on the electronic device 200. Then, the second sealing member 30 is located on the electronic device 200, and the second sloping surface 310 abuts against the first sloping surface 120. After that, the extending edges 45 of the two slidable covers 40 are slidably received in the guide groove 15 until the projections 124 are latched in the latching grooves 421 and the protrusions 122 are latched in the positioning groove 432. Thus, the sealing beams 44 abut against each other for further sealing the electronic device 200. The protective case 100 seals the electronic device 200 to prevent impurities, such as dust or water, from going into electronic device 200.

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A protective case used for protecting an electronic device, the protective case comprising:
a housing including a main plate and a peripheral wall, the main plate and the peripheral cooperatively defining a receptacle;
a first sealing member received in the receptacle and secured on the main plate;
a second sealing member including a sealing ring for abutting against the peripheral wall; and
two slidable covers slidably engaging with the peripheral wall of the housing and latched to the housing.

2. The protective case of claim 1, wherein the second sealing member includes a reinforcing plate, the sealing ring surrounds a peripheral edge of the reinforcing plate.

3. The protective case of claim 2, wherein the reinforcing plate is made of plastics and the sealing ring is made of thermoplastic polyurethane, the reinforcing plate and the sealing ring are integrally formed with each other by dual-injection molding.

4. The protective case of claim 1, wherein the peripheral wall has a first sloping surface, the sealing ring has a second sloping surface for abutting against the first sloping surface.

5. The protective case of claim 4, wherein the first sealing member is made of waterproof material and is adhered on the inside surface of the main plate by adhesive.

6. The protective case of claim 1, wherein the peripheral wall defines a guide groove, which extends continuously around all sides of the peripheral wall, each slidable cover has an extending edge slidably received in the guide groove.

7. The protective case of claim 6, wherein opposite ends of the peripheral wall have at least one protrusion, opposite sides of the guide groove have two projections, each slidable cover defines at least one positioning groove for engaging with the protrusion and a latching groove for engaging with the projections.

8. The protective case of claim 1, wherein one end of the slidable cover has a sealing beam for sealing a gap between the two slidable covers.

9. A protective case assembly comprising:
an electronic device;
a housing accommodating the electronic device;
a first sealing member received in the housing;
a second sealing member abutting against the housing; and
two slidable covers slidably engaging with the housing and latched to the housing;
wherein when the two slidable covers are latched to the housing, the first sealing member and the second sealing member contact with and protect the electronic device from damage.

10. The protective case assembly of claim 9, wherein the second sealing member includes a reinforcing plate and a sealing ring surrounding a peripheral edge of the reinforcing plate, the reinforcing plate is made of plastics and the sealing ring is made of thermoplastic polyurethane, the reinforcing plate and the sealing ring are integrally formed with each other by dual-injection molding.

11. The protective case assembly of claim 10, wherein the first sealing member is made of waterproof material and is adhered on the inside surface of the housing by adhesive.

12. The protective case assembly of claim 11, wherein the housing includes a main plate and a peripheral wall, the main plate and the peripheral cooperatively defining a receptacle, the peripheral wall defines a guide groove, which extends continuously around all sides of the peripheral wall, each slidable cover has an extending edge slidably received in the guide groove.

13. The protective case assembly of claim 11, wherein opposite ends of the peripheral wall have at least one protrusion, opposite sides of the guide groove have two projections, each slidable cover defines at least one positioning groove for engaging with the protrusion and a latching groove for engaging with the projections.
